(19) United States
(12) Patent Application Publication
(10) Pub. No.: US 2026/0025148 A1
(43) Pub. Date: Jan. 22, 2026

(54) SUCCESSIVE APPROXIMATION REGISTER ANALOG-TO-DIGITAL CONVERTER WITH EMBEDDED ENCODER FOR NON-BINARY UNIT ARRAY

(71) Applicant: MEDIATEK INC., Hsinchu City (TW)

(72) Inventors: Henry Arnold Park, San Jose, CA (US); Tamer Mohammed Ali, San Jose, CA (US)

(73) Assignee: MEDIATEK INC., Hsinchu City (TW)

(21) Appl. No.: 19/271,823

(22) Filed: Jul. 17, 2025

Related U.S. Application Data
(60) Provisional application No. 63/673,925, filed on Jul. 22, 2024.

(51) Int. Cl. H03M 1/46; H03M 1/14

(52) U.S. Cl. CPC H03M 1/462; H03M 1/14

(57) ABSTRACT

A successive approximation register (SAR) analog-to-digital converter (ADC) includes a capacitive digital-to-analog converter (DAC) including a capacitive DAC array implemented with a combination of non-binary units and binary units, a comparator, a SAR logic circuit and an encoder. The comparator compares the DAC output signal with a predetermined voltage level to generate the comparison result. The SAR logic circuit determines a plurality of bits according to the comparison result, and controls setting of the capacitive DAC in order to generate a set of first bits and a set of second bits among the plurality of bits with aid of a first sub-array and a second sub-array of the capacitive DAC array, respectively. The encoder encodes the set of first bits into a set of third bits, allowing the SAR ADC to output the set of third bits and the set of second bits as output bits of the SAR ADC.

### CROSS REFERENCE TO RELATED APPLICATIONS

This application claims the benefit of U.S. Provisional Application No. 63/673,925, filed on Jul. 22, 2024. The content of the application is incorporated herein by reference.

### BACKGROUND

The present invention is related to circuit design, and more particularly, to a successive approximation register (SAR) analog-to-digital converter (ADC) with an embedded encoder for a non-binary unit array.

According to the related art, one of multiple sub-circuits of a SAR ADC may be implemented as a capacitive digital-to-analog converter (DAC) such as a DAC equipped with a series of capacitors on internal signal paths of the DAC, for generating an output corresponding to a digital code in any cycle among multiple cycles, allowing the SAR ADC to perform signal comparison accordingly and selectively add or subtract a reference level to/from the current DAC output voltage in a next cycle. When the SAR ADC is operating according to a binary coding control scheme, the reference level may keep scaling down by 2. Some problems such as the capacitive-DAC settling error, the differential nonlinearity (DNL) caused by unit cap mismatch, etc. may have become a bottleneck. The latest SAR ADC design trend is to use non-binary coding, in order to try dealing with the issues in the related art, but further problems such as some side effects may be introduced. For example, the SAR ADC circuitry may become more complicated and require an extra latency. In a special case, the extra latency may be a latency of one extra full cycle, such as one extra full cycle latency. Thus, a novel architecture is needed for solving the problems without introducing any side effect or in a way that is less likely to introduce a side effect.

### SUMMARY

It is an objective of the present invention to provide a SAR ADC with an embedded encoder for a non-binary unit array, in order to solve the above-mentioned problems.

At least one embodiment of the present invention provides a SAR ADC (or “the SARADC”) with an embedded encoder for a non-binary unit array, where the SARADC may comprise a capacitive DAC, a comparator coupled to the capacitive DAC, a SAR logic circuit coupled to the capacitive DAC and the comparator, and an encoder coupled to the SAR logic circuit. The capacitive DAC may comprise a capacitive DAC array which is implemented with a combination of non-binary units and binary units, where the capacitive DAC array may comprise a first sub-array and a second sub-array. The capacitive DAC may be arranged to generate at least one DAC output signal. The comparator may be arranged to compare the aforementioned at least one DAC output signal with a predetermined voltage level to generate at least one comparison result. In addition, the SAR logic circuit may be arranged to determine a plurality of bits according to the at least one comparison result, where the SAR logic circuit may control setting of the capacitive DAC in order to generate a set of first bits and a set of second bits among the plurality of bits with the aid of the first sub-array and the second sub-array, respectively, for being output via a first signal path and a second signal path of the SAR logic circuit, respectively. Additionally, the encoder which is coupled between the first signal path and the second signal path of the SAR logic circuit to act as the embedded encoder may be arranged to receive the set of first bits via the first signal path and encode the set of first bits into a set of third bits, allowing the SARADC to output the set of third bits and the set of second bits as output bits of the SARADC.

It is an advantage of the present invention that, through proper design, the SARADC of the present invention can operate in an efficient manner, and more particularly, can hide the full adder (FA) delay into a portion of cycles among multiple computation cycles of the SARADC, to enhance the overall performance. In addition, the SARADC of the present invention can solve the related art problems without introducing any side effect or in a way that is less likely to introduce a side effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a SARADC with an embedded encoder for a non-binary unit array according to an embodiment of the present invention.

FIG. 2 illustrates, in the sub-diagrams (a) and (b) thereof, a binary coding control scheme which is applicable to a SARADC and the associated capacitive DAC, respectively.

FIG. 3 illustrates, in the sub-diagrams (a) and (b) thereof, a non-binary coding control scheme which is applicable to a SARADC and the associated architecture, respectively.

FIG. 4A is a block diagram illustrating the SARADC shown in FIG. 1 that is equipped with the embedded encoder for the non-binary unit array according to an embodiment of the present invention.

FIG. 4B is a block diagram illustrating a special case of the SARADC shown in FIG. 4A according to an embodiment of the present invention.

FIG. 5 illustrates an embedded location of the embedded encoder in a hybrid coding control scheme in comparison with an outside location of a non-embedded encoder in the non-binary coding control scheme shown in FIG. 3 according to an embodiment of the present invention, where the hybrid coding control scheme is applicable to the SARADC shown in any figure among FIG. 1, FIG. 4A and FIG. 4B.

FIG. 6 illustrates some implementation details of the hybrid coding control scheme shown in FIG. 5 according to an embodiment of the present invention.

FIG. 7 illustrates a timing diagram chart of the hybrid coding control scheme shown in FIG. 5 according to an embodiment of the present invention.

FIG. 8 illustrates more implementation details of the hybrid coding control scheme shown in FIG. 5 according to an embodiment of the present invention.

FIG. 9 illustrates, in the lower half part thereof, a control sequence of the hybrid coding control scheme shown in FIG. 5 according to an embodiment of the present invention, where a control sequence of the non-binary coding control scheme shown in FIG. 3 is illustrated in the upper half part of FIG. 9 for better comprehension.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

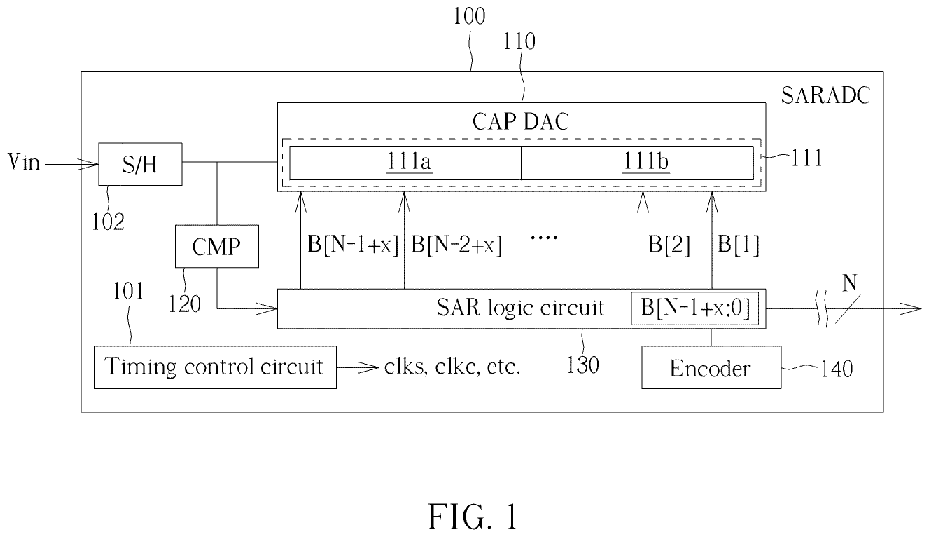

FIG. 1 is a block diagram illustrating a SARADC 100 with an embedded encoder for a non-binary unit array according to an embodiment of the present invention. The SARADC 100 may comprise a timing control circuit 101, a sample and hold circuit 102 (labeled “S/H” for brevity), a capacitive DAC 110 (labeled “CAP DAC” for brevity), a comparator 120 (labeled “CMP” for brevity), a SAR logic circuit 130 and an encoder 140. The capacitive DAC 110 may comprise a capacitive DAC array 111 which is implemented with a combination of non-binary units and binary units, where the capacitive DAC array 111 may comprise a first sub-array 111a and a second sub-array 111b. The timing control circuit 101 may perform timing control on other components within the SARADC 100, and more particularly, generate timing control signals such as clock signals clks and clkc, etc., and the sample and hold circuit 102 may perform sample and hold operations on an input signal Vin to capture an a value of the input signal Vin at a certain moment and hold it constant for a certain amount of time, allowing the SARADC 100 to determine output bits thereof such as N output bits according to the input signal Vin. For example, the capacitive DAC 110 may be implemented as a DAC equipped with a series of capacitors that are positioned on internal signal paths of the DAC, respectively, for generating an output corresponding to a digital code in any cycle among multiple cycles during a successive approximation procedure, allowing the SARADC 100 to perform signal comparison accordingly and selectively add or subtract a reference level to/from the current DAC output voltage in a next cycle.

During the successive approximation procedure, the capacitive DAC 110 may be arranged to generate at least one DAC output signal, and the comparator 120 may be arranged to compare the aforementioned at least one DAC output signal with a predetermined voltage level to generate at least one comparison result. For example, the predetermined voltage level is a ground voltage level such as a zero (0) voltage level. In addition, the SAR logic circuit 130 may be arranged to determine a plurality of bits B[N−1+x], B[N−2+x], . . . , B[3], B[2], B[1] and B[0], which may be collectively referred to as the bits B[(N−1+x):0] (or “B[N−1+x:0]” for brevity), according to the aforementioned at least one comparison result, where the SAR logic circuit 130 may control the setting of the capacitive DAC 110 in order to generate a set of first bits {B[ ]} such as the bits {B[N−1+x], B[N−2+x], . . . , B[3]} and a set of second bits {B[ ]} such as the bits {B[2], B[1] and B[0]} among the plurality of bits B[N−1+x], B[N−2+x], . . . , B[3], B[2], B[1] and B[0] with the aid of the first sub-array 111a and the second sub-array 111b, respectively, for being output via a first signal path and a second signal path of the SAR logic circuit 130, respectively. Additionally, the encoder 140 which is coupled between the first signal path and the second signal path of the SAR logic circuit 130 to act as the embedded encoder may be arranged to receive the set of first bits {B[ ]} via the first signal path and encode the set of first bits {B[ ]} (e.g., the bits {B[N−1+x], B[N−2+x], . . . , B[3]} into a set of third bits {B′[ ]} (e.g., the bits {B′[N−1], B′[N−2], . . . , B′[3]}), allowing the SARADC 100 to output the set of third bits {B′[ ]} (e.g., {B′[N−1], B′[N−2], . . . , B′[3]}) and the set of second bits {B[ ]} (e.g., the bits {B[2], B[1] and B[0]}) as the output bits of the SARADC 100, such as the N output bits.

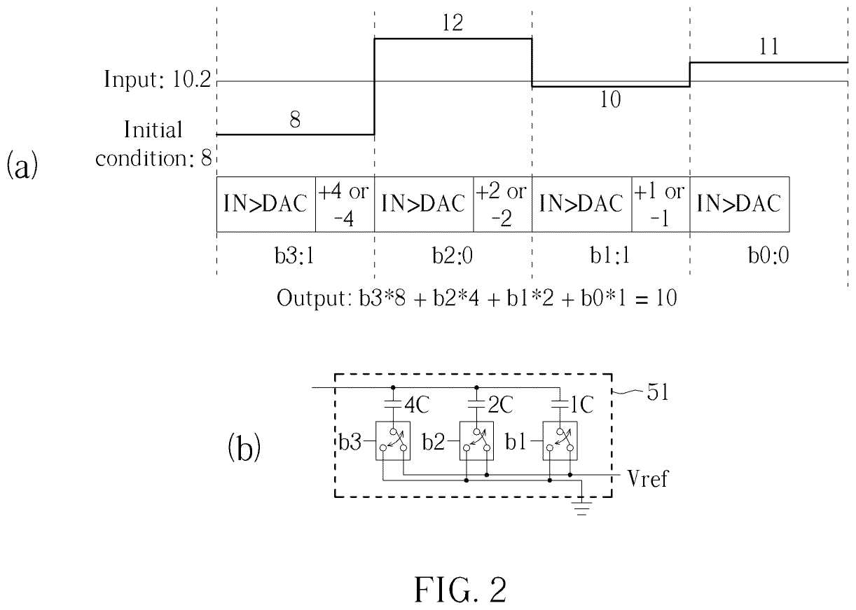

FIG. 2 illustrates, in the sub-diagrams (a) and (b) thereof, a binary coding control scheme which is applicable to a SARADC and the associated capacitive DAC 51, respectively. For better comprehension, assume that the whole of the capacitive DAC array 111 may be implemented with binary units rather than the aforementioned combination of non-binary units and binary units, as if the second sub-array 111b may be expanded to occupy the whole of the capacitive DAC array 111, making the size of the first sub-array 111a become zero and making the encoder 140 be removed, to allow the SARADC 100 to operate according to the binary coding control scheme shown in FIG. 2, but the present invention is not limited thereto. Based on the binary coding control scheme, in a situation where “C” stands for a predetermined unit capacitance value, when N=4 and x=0, the series of capacitors that are positioned on the internal signal paths of the DAC may have the capacitance values of 4C, 2C and 1C, respectively, and the capacitive DAC 110 may be simplified as the capacitive DAC 51 shown in the sub-diagram (b) of FIG. 2. The plurality of bits B[N−1+x], B[N−2+x], . . . , B[3], B[2], B[1] and B[0] may be written as the bits b3, b2, b1 and b0. As shown in the sub-diagram (a) of FIG. 2, in each cycle, the input signal Vin is compared to a DAC output of the capacitive DAC 51 (labeled “IN>DAC” for brevity) to generate a comparison result indicating whether the input signal Vin is greater than the DAC output. The comparison result decides whether to add or subtract a reference level to the current DAC output voltage. It continues until the final decision is made. The reference level keeps scaling down by 2 (binary coding).

For example, the input of this SARADC architecture, such as the voltage level of the input signal Vin, may be equal to 10.2 (Volt, or “V”), and the initial condition of this SARADC architecture, such as the initial DAC output in the first cycle, may be equal to 8 (V) corresponding to b3=1. The reference level to be added to or subtracted from the current DAC output voltage in the second cycle, the third cycle and the fourth cycle may be equal to {4, 2, 1} (V), respectively, and the associated determination operations regarding whether to add or subtract the reference level in the second cycle to the fourth cycle should be completed before the respective end of the previous cycles such as the first cycle to the third cycle (respectively labeled “+4 or −4”, “+2 or −2” and “+1 or −1” for brevity). As the respective comparison results of “IN>DAC?” in the first cycle, the second cycle, the third cycle and the fourth cycle may be equal to the logic states {True, False, True, False}, respectively, which may be expressed with the logic values {1, 0, 1, 0}, respectively, the bits b3, b2, b1 and b0 may be determined as the logic values {1, 0, 1, 0}, respectively. As a result, the output may be equal to (4*2*b3)+(2*2*b2)+(1*2*b1)+(0.5*2*b0), that is, (8*b3)+(4*b2)+(2*b1)+(1*b0)=10 (labeled “b3*8+b2*4+b1*2+b0*1=10” for brevity). The SARADC architecture of the binary coding control scheme shown in FIG. 2 will suffer from the problems such as the capacitive-DAC settling error, the DNL, etc.

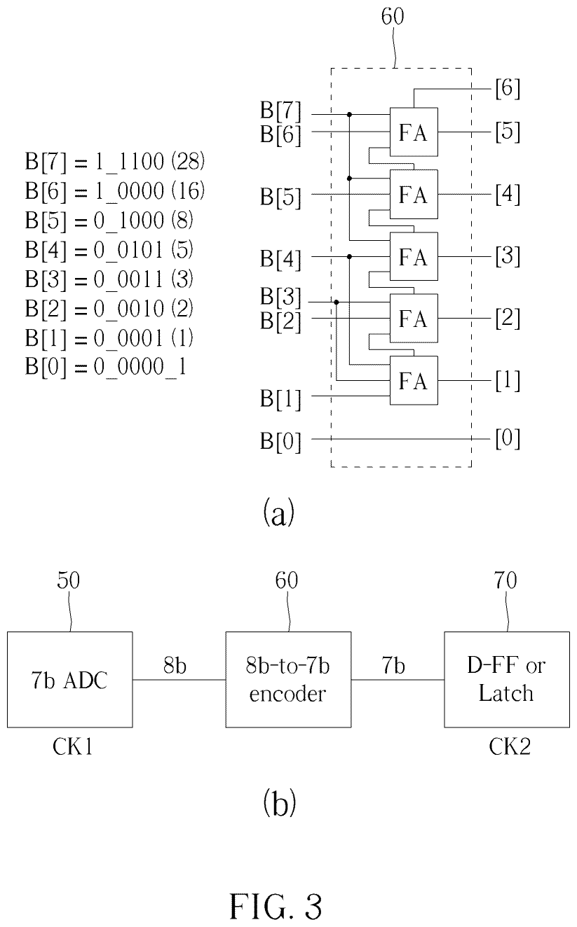

FIG. 3 illustrates, in the sub-diagrams (a) and (b) thereof, a non-binary coding control scheme which is applicable to a SARADC and the associated architecture, respectively. For better comprehension, assume that the whole of the capacitive DAC array 111 may be implemented with non-binary units rather than the aforementioned combination of non-binary units and binary units, as if the first sub-array 111a may be expanded to occupy the whole of the capacitive DAC array 111, making the size of the second sub-array 111b become zero and making the encoder 140 become a non-embedded encoder outside the main ADC architecture, to allow the SARADC 100 to operate according to the non-binary coding control scheme shown in FIG. 3, but the present invention is not limited thereto. Based on the non-binary coding control scheme, in a situation where “C” stands for the predetermined unit capacitance value, when N=7 and x=1, the series of capacitors that are positioned on the internal signal paths of the DAC may have the capacitance values of 28C, 16C, 8C, 5C, 3C, 2C and 1C, respectively. As shown in the sub-diagram (b) of FIG. 3, the main ADC architecture may be regarded as an ADC 50 corresponding to a seven-bit output design (labeled “7b ADC” for brevity), and the non-embedded encoder outside the main ADC architecture may be regarded as an eight bit to seven bit (8b-to-7b) encoder 60 for converting the 8 bits (8b) from the ADC 50 into 7 bit (7b) for being output via an additional output stage 70 such as a D-type flip flop (D-FF) or a latch (labeled “D-FF or Latch” for brevity).

For example, there may be a non-binary scaling relationship between the bits B[7:0] and the bits B′[6:0]. As shown in the sub-diagram (a) of FIG. 3, the first seven bits B[7:1] among the bits B[7:0], starting from the most significant bit (MSB) B[7] thereof, may correspond to the weights determined by the capacitance values {28C, 16C, 8C, 5C, 3C, 2C, 1C} of the series of capacitors (labeled {28, 16, 8, 5, 3, 2, 1} for brevity), respectively, and therefore may be expressed with equivalent binary values {1_1100, 1_0000, 0_1000, 0_0101, 0_0011, 0_0010, 0_0001, 0_0000_1}, respectively, and the least significant bit (LSB) B[0] of the bits B[7:0] may be expressed with another equivalent binary value 0_0000_1 having one more digit to indicate that B[0]=B′[0]. The 8b-to-7b encoder 60 may comprise five full adders (FAs) for converting the bits B[7:0] into the bits B′[6:0]. The output may be equal to (28*2*B[7])+(16*2*B[6])+(8*2*B[5])+(5*2*B[4])+(3*2*B[3])+(2*2*B[2])+(1*2*B[1])+(0.5*2*B[0]), that is, (56*B[7])+(32*B[6])+(16*B[5])+(10*B[4])+(6*B[3])+(4*B[2])+(2*B[1])+(1*B[0]). In the SARADC architecture of the non-binary coding control scheme shown in FIG. 3, as the 8b-to-7b encoder 60 which is positioned outside the main ADC architecture such as the ADC 50 is needed, the 8b-to-7b encoder 60 requires the extra latency corresponding to the five FAs (e.g., the five FAs' delay). In addition, the clock CK2 for operating the additional output stage 70 such as the D-FF or the latch can be same as the clock CK1 for operating the ADC 50, which means one extra full cycle latency is required.

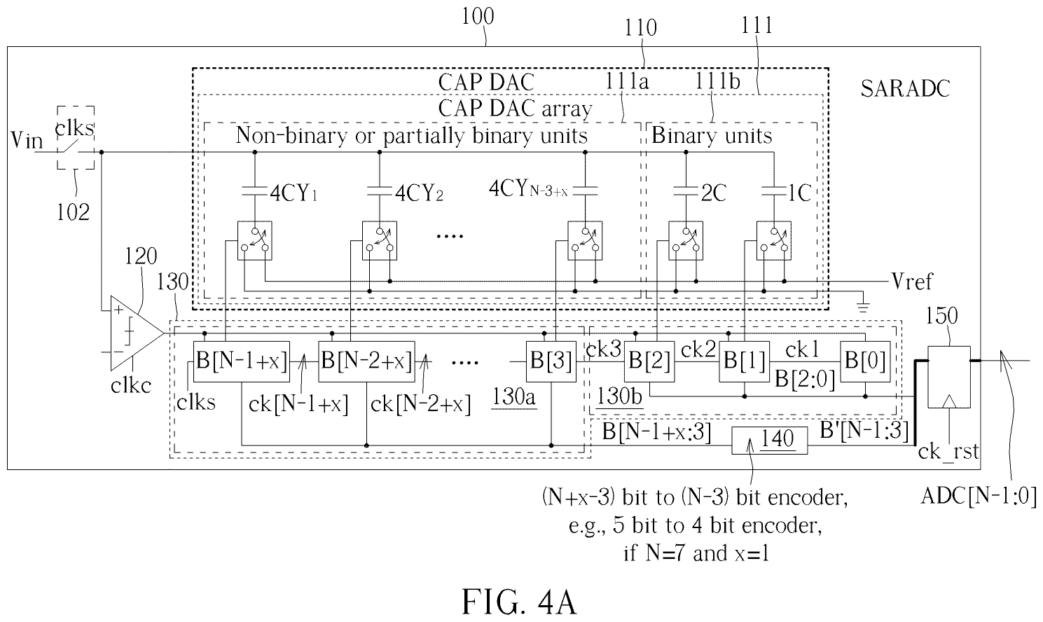

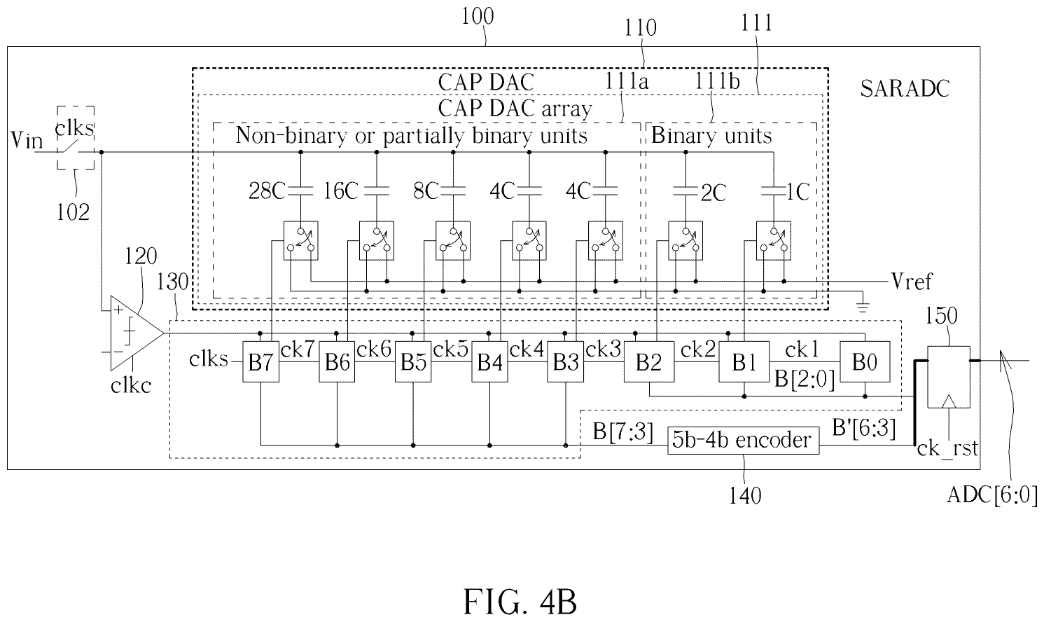

FIG. 4A is a block diagram illustrating the SARADC 100 shown in FIG. 1 that is equipped with the embedded encoder (e.g., the encoder 140) for the non-binary unit array according to an embodiment of the present invention. As shown in FIG. 4A, the sample and hold circuit 102 can be implemented as a switch operating according to the clock signal clks. Among a series of units within the capacitive DAC array 111 (labeled “CAP DAC array” for brevity), such as the series of units comprising the aforementioned combination of non-binary units and binary units, the last two units are fully binary, and the other units are non-binary or partially binary (e.g., a binary plus non-binary combination in which there are some binary units and some non-binary units), where the second sub-array 111b comprises the last two units that are fully binary among the series of units (labeled “Binary units” for brevity), and the first sub-array 111a comprises the other binary units that are non-binary or partially binary among the series of units (labeled “Non-binary or partially binary units” for brevity). Based on the architecture shown in FIG. 4A, the set of second bits {B[ ]} are consecutive bits {B[i]|i=2, 1, 0} comprising the LSB B[0] among the plurality of bits B[N−1+x], B[N−2+x], . . . , B[3], B[2], B[1] and B[0], and the set of first bits {B[ ]} are the other consecutive bits {B[i] |i=(N−1+x), (N−2+x), . . . , 3} comprising the MSB B[N−1+x] among the plurality of bits B[N−1+x], B[N−2+x], . . . , B[3], B[2], B[1] and B[0]. In addition, any bit B[ ] among the plurality of bits B[N−1+x], B[N−2+x], . . . , B[3], B[2], B[1] and B[0] can be arranged to control a corresponding capacitive unit in the capacitive DAC 110 (or the capacitive DAC array 111 thereof). As shown in FIG. 4A, the SAR logic circuit 130 may comprise a series of registers for storing the plurality of bits B[N−1+x], B[N−2+x], . . . , B[3], B[2], B[1] and B[0], and the series of registers may be illustrated with small boxes having the plurality of bits B[N−1+x], B[N−2+x], . . . , B[3], B[2], B[1] and B[0] labeled thereon for better comprehension. The series of registers may operate according to the clock signal clks and the subsequent clock signals ck [N−1+x], ck [N−2+x], . . . , ck3, ck2 and ck1.

The SARADC 100 can be regarded as an N-bit SARADC whose output bits are N output bits ADC[N−1:0], and the plurality of bits B[N−1+x], B[N−2+x], . . . , B[3], B[2], B[1] and B[0] can be (N+x) bits such as the bits B[(N−1+x):0], where “N” is a positive integer at least greater than three, such as a positive integer much greater than three as long as implementation of the SARADC 100 will not be hindered, and “x” is a positive integer. In addition, the set of first bits {B[ ]} comprise the bits B[(N−1+x):3] among the bits B[(N−1+x):0], and the set of second bits {B[ ]} comprise the bits B[2:0] among the bits B[(N−1+x):0]. The set of third bits {B′[ ]} comprise the bits B′[(N−1):3], and the N output bits comprise both of the bits B′[(N−1):3] and the bits B[2:0]. Among the series of capacitors that are positioned on the internal signal paths of the DAC, a series of first capacitors within the first sub-array 111a, such as the series of first capacitors corresponding to the bits B[(N−1+x):3], have the capacitance values of [(4C*Y₁):(4C*Y_{N-3+x})], respectively, and a series of second capacitors within the second sub-array 111b, such as the series of second capacitors corresponding to the bits B[2:1] among the bits B[2:0], have the capacitance values of [2C:1C], respectively, where “C” is the predetermined unit capacitance value, and Y₁ to Y_{N-3+x} are positive integers. Additionally, the summation ((4C*Y₁)+(4C*Y₂)+ . . . +(4C*Y_{N-3+x})+2C+1C) of the capacitance values {(4C*Y₁), (4C*Y₂), . . . , (4C*Y_{N-3+x})} of the series of first capacitors and the capacitance values {2C, 1C} of the series of second capacitors is equal to ((2^{(N-1)}−1)*C). In other words, the total number of the unit capacitor in the capacitive DAC array 111, such as the total size of the series of capacitors that is measured in unit of the predetermined unit capacitance value C, is equal to (2^{(N-1)}−1). As shown in FIG. 4A, a series of switches corresponding to the series of capacitors are coupled to the series of registers in the SAR logic circuit 130. More particularly, among the series of switches, a series of first switches coupled to the series of first capacitors within the first sub-array 111a are controlled by a series of first registers 130a among the series of registers to switch between the signal path of the reference voltage Vref and the signal path of the ground (or the ground voltage), respectively, and a series of second switches coupled to the series of second capacitors within the second sub-array 111b are controlled by a series of second registers 130b among the series of registers to switch between the signal path of the reference voltage Vref and the signal path of the ground (or the ground voltage), respectively.

The encoder 140 can be an (N+x−3) bit to (N−3) bit encoder (e.g., a five bit to four bit (5b-to-4b) encoder, if N=7 and x=1) for performing encoding processing on the set of first bits {B[ ]} such as the bits B[(N−1+x):3] to generate the set of third bits {B′[ ]} such as the bits B′[(N−1):3], where the encoding processing may comprise receiving the set of first bits {B[ ]} as multiple non-binary input codes and summing up the multiple non-binary input codes with scaling factors that are determined by the corresponding unit cap sizes of the series of first capacitors within the first sub-array 111a. For example, the encoder 140 such as the (N+x−3) bit to (N−3) bit encoder can perform the encoding processing on the bits B[(N−1+x):3] to generate the bits B′[(N−1):3] according to the following equation:

$$( B [ N - 1 + x ] * 4 {Y}_{1} ) + ( B [ N - 2 + x ] * 4 {Y}_{2} ) + … + ( B [ 3 ] * 4 {Y}_{N - 3 + x} ) = {B}^{′} [ ( N - 1 ) : 3 ] .$$

At the end of a cycle (e.g., the last cycle) in which the LSB B[0] is resolved among the multiple cycles of the SARADC 100, the SARADC 100 is arranged to start outputting the set of third bits {B′[ ]} (e.g., the bits B′[(N−1):3]) and the set of second bits {B[ ]} (e.g., the bits B[2:0]) as the N output bits ADC[N−1:0] of the SARADC 100. As shown in FIG. 4A, the SARADC 100 may comprise an output stage 150 (e.g., a D-FF) operating according to a clock-reset signal ck_rst among the timing control signals of the timing control circuit 101, for outputting the N output bits ADC[N−1:0].

FIG. 4B is a block diagram illustrating a special case of the SARADC 100 shown in FIG. 4A according to an embodiment of the present invention. When N=7 and x=1, the plurality of bits B[N−1+x], B[N−2+x], . . . , B[3], B[2], B[1] and B[0] can be the bits B[7], B[6], B[5], B[4], B[3], B[2], B[1] and B[0] (or “the bits B7, B6, B5, B4, B3, B2, B1 and B0”), respectively. In addition, the bits B[(N−1+x):3] can be the bits B[7:3], the bits B′[(N−1):3] can be the bits B′[6:3], and the encoder 140 such as the (N+x−3) bit to (N−3) bit encoder can be the 5b-to-4b encoder (or “the 5b-4b encoder”). For example, the capacitance values {(4C*Y₁), (4C*Y₂), . . . , (4C*Y_{N-3+x})} of the series of first capacitors can be equal to {28C, 16C, 8C, 4C, 4C}, respectively, but the present invention is not limited thereto. For brevity, similar descriptions for this embodiment are not repeated in detail here.

According to some embodiments, for the case of N=7 and x=1, the capacitance values {(4C*Y₁), (4C*Y₂), . . . , (4C*Y_{N-3+x}), 2C, 1C} of the series of capacitors can be equal to any set of capacitance values among the following sets of capacitance values:
(1) {28C, 16C, 8C, 4C, 4C, 2C, 1C};
(2) {28C, 16C, 4C, 8C, 4C, 2C, 1C};
(3) {28C, 12C, 8C, 8C, 4C, 2C, 1C};
(4) {28C, 12C, 12C, 4C, 4C, 2C, 1C};
(5) {24C, 16C, 8C, 8C, 4C, 2C, 1C}; and
(6) {24C, 12C, 12C, 8C, 4C, 2C, 1C};
where the last two units in the capacitive DAC array 111 must be full binary, and the other five units must be an integer multiple of 4 times the minimum capacitor size (e.g. 1C). The total (or the summation/sum) of the capacitor values in all capacitive units within the capacitive DAC array 111 is equal to ((2^{(N-1)}−1)*C) with N=7, i.e., ((2⁶⁻¹)*C)=63C.

In general, the SARADC 100 such as the N-bit SARADC can be designed by the same rule, for example:
(1) the last two units in the capacitive DAC array 111 are fully binary, with the series of second capacitors having the capacitance values {2C, 1C}, respectively;
(2) the other units are non-binary or partially binary, in which each capacitance value among the capacitance values {(4C*Y₁), (4C*Y₂), . . . , (4C*Y_{N-3+x})} of the series of first capacitors must be an integer multiple of 4C;
(3) the total capacitance unit number/count, such as the count obtained from dividing the total of the capacitance values {(4C*Y₁), (4C*Y₂), . . . , (4C*Y_{N-3+x}), 2C, 1C} of the series of capacitors with the capacitive DAC array 111 by the predetermined unit capacitance value C, must be equal to (2^{(N-1)}−1);
(4) the encoder 140 converts the set of first bits {B[ ]} such as the bits B[(N−1+x):3] to the set of third bits {B′[ ]} such as the bits B′[(N−1):3] while the SARADC 100 is resolving the set of second bits {B[ ]} such as the bits B[2:0], where “x” is a positive integer; and
(5) the final ADC output such as the N output bits ADC[N−1:0] is the combined N-bit output of the bits B′[(N−1):3] and B[2:0], that is, the N bits {B′[(N−1):3], B[2:0]}.

For brevity, similar descriptions for these embodiments are not repeated in detail here.

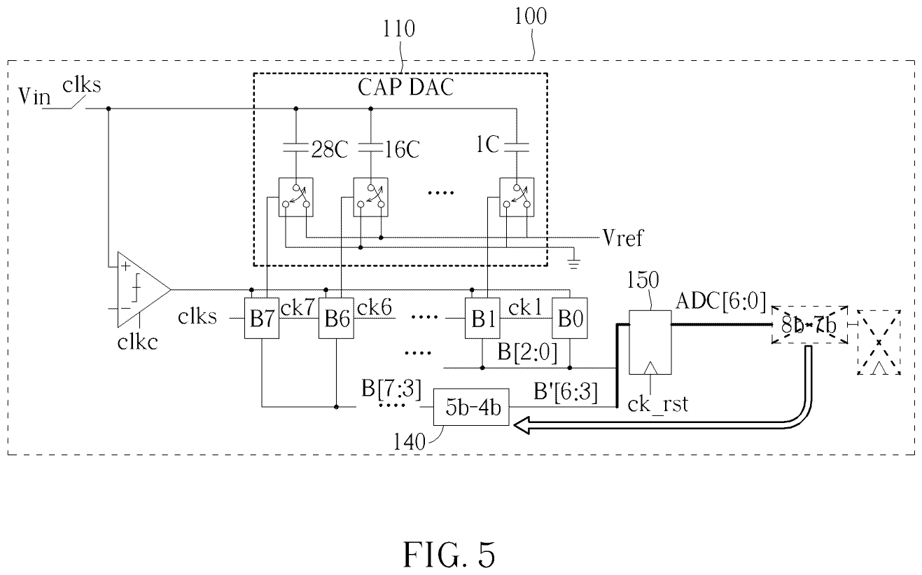

FIG. 5 illustrates an embedded location of the embedded encoder in a hybrid coding control scheme in comparison with an outside location of the non-embedded encoder in the non-binary coding control scheme shown in FIG. 3 according to an embodiment of the present invention, where the hybrid coding control scheme is applicable to the SARADC 100 shown in any figure among FIG. 1, FIG. 4A and FIG. 4B. Taking the case of N=7 and x=1 as an example, the encoder 140 is coupled between the first signal path and the second signal path of the SAR logic circuit 130 to act as the embedded encoder such as the 5b-to-4b encoder (labeled “5b-4b” for brevity) for converting the bits B[7:3] into the bits B′[6:3], having no need to be implemented as the non-embedded encoder such as the 8b-to-7b encoder 60 outside the main ADC architecture. Therefore, the SARADC 100 can complete the whole processing in time without any latency such as that (e.g., the extra latency corresponding to the five FAs plus the one extra full cycle latency) of the architecture shown in FIG. 3, to achieve better overall performance.

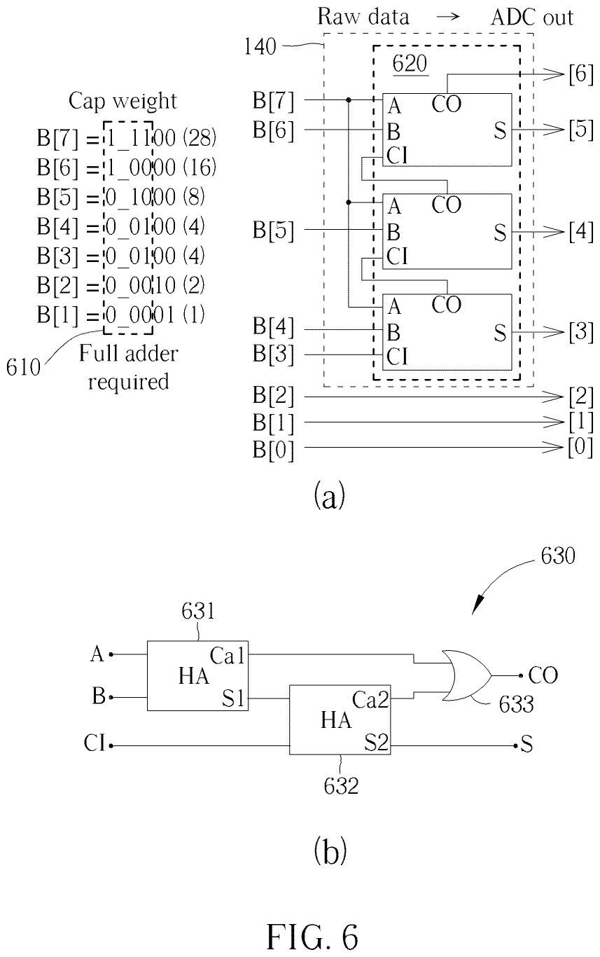

FIG. 6 illustrates some implementation details of the hybrid coding control scheme shown in FIG. 5 according to an embodiment of the present invention. The SARADC 100 can operate according to the hybrid coding control scheme to achieve the better overall performance. For example, when N=7 and x=1, the capacitance values {(4C*Y₁), (4C*cY₂), . . . , (4C*Y_{N-3+x}), 2C, 1C} of the series of capacitors can be equal to the set of capacitance values {28C, 16C, 8C, 4C, 4C, 2C, 1C}, respectively, but the present invention is not limited thereto. According to some embodiments, the capacitance values {(4C*Y₁), (4C*Y₂), . . . , (4C*Y_{N-3+x})} may vary as mentioned above.

In addition, there may be a non-binary scaling relationship between the bits B[7:3] and the bits B′[6:3]. As shown in the sub-diagram (a) of FIG. 6, the first seven bits B[7:1] among the bits B[7:0], starting from the MSB B[7] thereof, may correspond to capacitive weights (or “the Cap weights”) such as the weights determined by the capacitance values {28C, 16C, 8C, 4C, 4C, 2C, 1C} of the series of capacitors (labeled {28, 16, 8, 4, 4, 2, 1} for brevity), respectively, and therefore may be expressed with equivalent binary values {1_1100, 1_0000, 0_1000, 0_0100, 0_0100, 0_0010, 0_0001, 0_0000_1}, respectively. As the lower two digits of the equivalent binary values of the bits B[7:3] are full of zeros (0), only a few FAs are required for the higher digits 610. More particularly, the encoder 140 acting as the embedded encoder such as the 5b-to-4b encoder may comprise three FAs 620 for converting the bits B[7:3] into the bits B′[6:3] while keeping the bits B[2:0] unchanged, to make the ADC output (or “the ADC out”) such as the N output bits ADC[N−1:0] (e.g., ADC[6:0], if N=7) be equal to the combined 7-bit output of the bits B′[6:3] from the three FAs 620 and the bits B[2:0] among the raw data (i.e., the bits B[7:0]) of the SAR logic circuit 130. For example, any FA among the three FAs 620 may have three input terminals (labeled “A”, “B” and “CI”) for receiving a first input A, a second input B and a carry input CI of the FA, respectively, and may have two output terminals (labeled “CO” and “S”) for outputting a carry output CO and a final sum output S of the FA, respectively.

As shown in the sub-diagram (b) of FIG. 6, the aforementioned any FA such as the FA 630 may comprise two half adders 631 and 632 (labeled “HA” for brevity) and an OR gate 633, and any half adder among the half adders 631 and 632 may have two input terminals for receiving two inputs to be summed up by this half adder, a sum output terminal (labeled “S1” or “S2”) for outputting the sum (e.g., the sum S1 or the sum S2) of the two inputs of this half adder, and a carry output terminal (labeled “Ca1” or “Ca2”) for outputting the carry (e.g., the carry Ca1 or the carry Ca2) of this half adder. The two inputs of the half adder 631 may act as the first input A and the second input B of the FA 630, one of the two input terminals of the half adder 632 may be coupled to the sum output terminal (labeled “S1”) of the half adder 631 to receive the sum S1 from the half adder 631, and the input at the other of the two input terminals of the half adder 632 may act as the carry input CI of the FA 630. One of the two input terminals of the OR gate 633 may be coupled to the carry output terminal (labeled “Ca1”) of the half adder 631 to receive the carry Ca1 from the half adder 631, and the other of the two input terminals of the OR gate 633 may be coupled to the carry output terminal (labeled “Ca2”) of the half adder 632 to receive the carry Ca2 from the half adder 632. The output of the OR gate 633 may act as the carry output CO of the FA 630, and the sum S2 output by the half adder 632 may act as the final sum output S of the FA 630.

TABLE 1

| | |
|---|---|
| Input | Output |

| A | B | CI | CO | S |
|---|---|---|---|---|
| 0 | 0 | 0 | 0 | 0 |
| 0 | 0 | 1 | 0 | 1 |
| 0 | 1 | 0 | 0 | 1 |
| 0 | 1 | 1 | 1 | 0 |
| 1 | 0 | 0 | 0 | 1 |
| 1 | 0 | 1 | 1 | 0 |
| 1 | 1 | 0 | 1 | 0 |
| 1 | 1 | 1 | 1 | 1 |

Table 1 illustrates an example of the truth table of the FA, where the aforementioned any FA among the three FAs 620, such as the FA 630, may operate according to the truth table shown in Table 1.

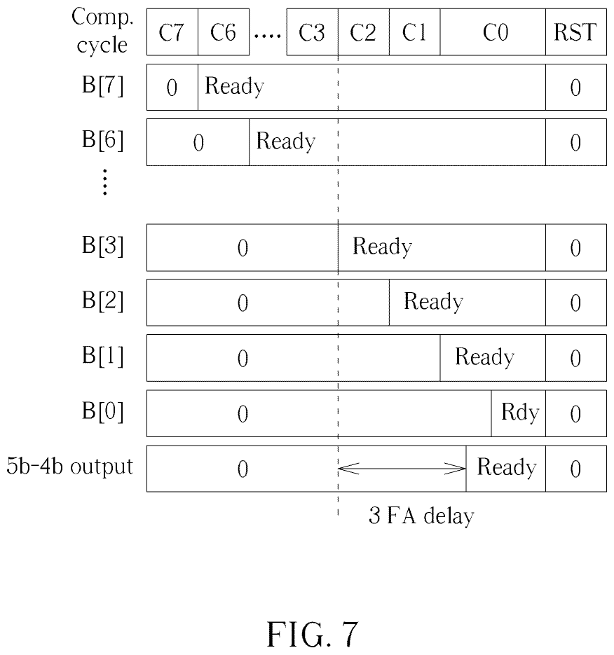

FIG. 7 illustrates a timing diagram chart of the hybrid coding control scheme shown in FIG. 5 according to an embodiment of the present invention. The SARADC 100 (or the SAR logic circuit 130 therein) can be arranged to complete the bit B[ ] determination operations, that is, the operations of determining the plurality of bits B[N−1+x], B[N−2+x], . . . , B[3], B[2], B[1] and B[0] (e.g., the bits B[7:0], if N=7 and x=1), at the multiple cycles such as (N+x) computation (Comp.) cycles C[N−1+x], C[N−2+x], . . . , C[3], C[2], C[1] and C[0] (e.g., the computation cycles C[7:0], if N=7 and x=1), respectively. After the LSB B[0] is resolved, the SARADC 100 can be arranged to utilize the output stage 150 of the SARADC 100 to sample the set of third bits {B′[ ]} such as the bits B′[(N−1):3] (e.g., the bits B′[6:3], if N=7) and the set of second bits {B[ ]} such as the bits B[2:0] as the N output bits ADC[N−1:0] of the SARADC 100, for being output from the SARADC 100. The SARADC 100 can utilize the output stage 150 to output the N output bits ADC[N−1:0] before entering a reset cycle RST, and then reset the series of registers within the SAR logic circuit 130 as well as the encoder 140 such as the (N+x−3) bit to (N−3) bit encoder (e.g., the 5b-to-4b encoder, if N=7 and x=1) in the reset cycle RST. For better comprehension, the bits B[7:0] and the 5b-4b output (i.e., the output of the encoder 140 such as the 5b-to-4b encoder) can be illustrated as zero (0) before the determination thereof is ready (labeled “Ready” or “Rdy” which also stands for ready) and after entering the reset cycle RST, but the present invention is not limited thereto.

The SARADC 100 (or the encoder 140 therein) can be arranged to complete the (N+x−3) bit to (N−3) bit encoding operations (or the bit B[ ] to bit B′[ ] encoding operations), that is, the operations of encoding the set of first bits {B[ ]} such as the bits B[(N−1+x):3] (e.g., the bits B[7:3], if N=7 and x=1) into the set of third bits {B′[ ]} such as the bits B′[(N−1):3] (e.g., the bits B′[6:3], if N=7), before the end of the cycle (e.g., the computation cycle C0) in which the LSB B[0] is resolved, for hiding the associated encoding time, that is, the encoding time of encoding the set of first bits {B[ ]} into the set of third bits {B′[ ]} by the encoder 140, into a portion of cycles among the multiple cycles of the SARADC 100. As the FA count of the FAs 620 in the encoder 140 shown in FIG. 6 is merely equal to three, the total delay between the beginning and the end of the encoding by the encoder 140 is just the delay of the three FAs 620 (labeled “3 FA delay” for brevity), and such delay can be hidden in the portion of cycles such as the computation cycles {C2, C1, C0}. As the reset cycle RST comes after the multiple cycles such as the (N+x) computation cycles C[N−1+x], C[N−2+x], . . . , C[3], C[2], C[1] and C[0] (e.g., the computation cycles C[7:0], if N=7 and x=1), rather than being one of the multiple cycles, the portion of cycles such as the computation cycles {C2, C1, C0} can be regarded as the last portion of cycles among the multiple cycles of the SARADC 100.

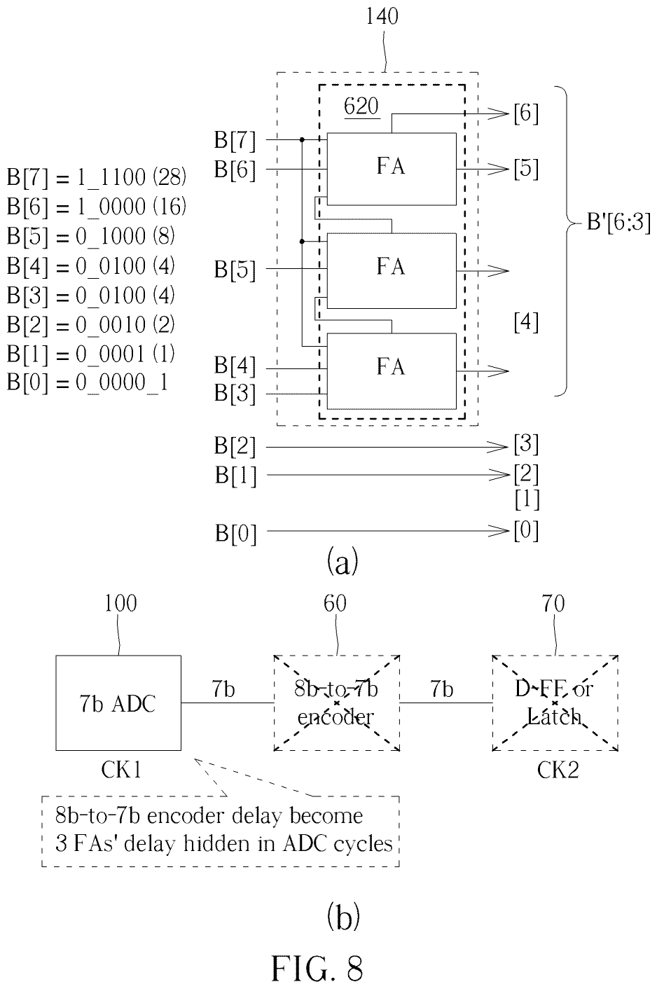

FIG. 8 illustrates more implementation details of the hybrid coding control scheme shown in FIG. 5 according to an embodiment of the present invention. As shown in the sub-diagram (a) of FIG. 8, the first seven bits B[7:1] starting from the MSB B[7] among the bits B[7:0] may be expressed with the equivalent binary values {1_1100, 1_0000, 0_1000, 0_0100, 0_0100, 0_0010, 0_0001, 0_0000_1}, respectively, and the LSB B[0] of the bits B[7:0] may be expressed with another equivalent binary value 0_0000_1 having one more digit to indicate that B[0]=B′[0]. In addition, the LSB B[0] among the bits B[7:0] does not have a dedicated capacitive unit within the capacitive DAC array 111, but it is assumed to have an imaginary unit capacitor with the size of 0.5C. More particularly, the series of second capacitors plus the imaginary unit capacitor respectively corresponding to the last three bits B[2], B[1] and B[0] among the bits B[7:0] must be fully binary to have the capacitance values {2C, 1C, 0.5C}, respectively, and the series of first capacitors respectively corresponding to the other bits B[7], B[6], B[5], B[4] and B[3] must be non-binary or partially binary to have the capacitance values {(4C*Yⱼ)|j=1, 2, . . . , (N−3+x)} such as the capacitance values {(4C*Yⱼ)|j=1, 2, 3, 4, 5}, respectively, each of which is an integer multiple of 4. For example, assuming that the predetermined unit capacitance value C may be equal to one, when the capacitor parameters {Yⱼ|j=1, 2, . . . , (N−3+x)} such as the capacitor parameters {Yⱼ|j=1, 2, 3, 4, 5} (or the parameters {Y₁, Y₂, Y₃, Y₄, Y₅}) is equal to {7, 4, 2, 1, 1}, the capacitance value corresponding to the bit B[7] is equal to (4*7)=28, the capacitance value corresponding to the bit B[6] is equal to (4*4)=16, the capacitance value corresponding to the bit B[5] is equal to (4*2)=8, and both of the capacitance values respectively corresponding to the bits B[4] and B[3] are equal to (4*1)=4. Additionally, after the encoding by the encoder 140 is completed within the portion of cycles such as the computation cycles {C2, C1, C0}, the SARADC 100 has obtained the bits B′[6:3]. After both of the bits B′[6:3] and the LSB B[0] (in particular, the bits B[2:0]) have been obtained in the computation cycle C0, the SARADC 100 can utilize the output stage 150 to sample the bits B′[6:3] and the bits B[2:0] as the seven output bits ADC[6:0] such as the bits {ADC[6], ADC[5], ADC[4], ADC[3], ADC[2], ADC[1], ADC[0]} (labeled {[6], [5], [4], [3], [2], [1], [0]} for brevity), for being output from the SARADC 100.

As shown in the sub-diagram (b) of FIG. 8, the SARADC 100 such as the N-bit SARADC (e.g., the 7-bit SARADC, if N=7) itself can act as the main ADC architecture in the hybrid coding control scheme shown in FIG. 5, having no need to implement any additional subsequent stages such as that (e.g., the 8b-to-7b encoder 60 and the additional output stage 70) of the non-binary coding control scheme shown in FIG. 3. The SARADC 100 that is equipped with the embedded encoder (e.g., the encoder 140) can complete the whole processing in time without any latency such as that (e.g., the extra latency corresponding to the five FAs plus the one extra full cycle latency) of the architecture shown in FIG. 3. Assuming that the SARADC 100 is operating according to the same clock CK1 as that shown in FIG. 3, as the 8b-to-7b encoder delay has become the three FAs' delay hidden in the ADC cycles, the SARADC 100 can achieve much higher performance than that of the architecture shown in FIG. 3.

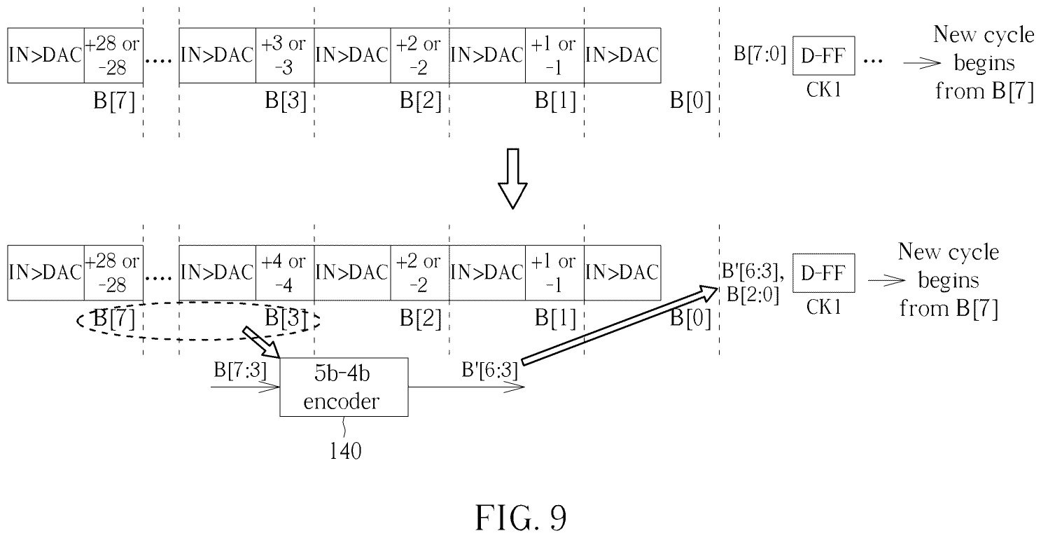

FIG. 9 illustrates, in the lower half part thereof, a control sequence of the hybrid coding control scheme shown in FIG. 5 according to an embodiment of the present invention, where a control sequence of the non-binary coding control scheme shown in FIG. 3 is illustrated in the upper half part of FIG. 9 for better comprehension. These control sequence are illustrated with respect to time (or the time axis) along the horizontal direction, and the vertical lines depicted with dashed lines are illustrated for indicating the time points of cycle switching. In the control sequence of the non-binary coding control scheme, when N=7 and x=1, with the series of capacitors in the main ADC architecture thereof such as the ADC 50 having the capacitance values {28C, 16C, 8C, 5C, 3C, 2C, 1C}, respectively, the total latency which comprises the extra latency corresponding to the five FAs and the one extra full cycle latency mentioned above is illustrated with “ . . . ” as shown in the upper right corner of FIG. 9, and would be considered unacceptable in the latest high speed applications. In the control sequence of the hybrid coding control scheme, taking the case of N=7 and x=1 as an example, with the capacitance values {(4C*Y₁), (4C*Y₂), . . . , (4C*Y_{N-3+x}), 2C, 1C} of the series of capacitors in the SARADC 100 being configured as having the set of capacitance values {28C, 16C, 8C, 4C, 4C, 2C, 1C}, respectively, the aforementioned total latency no longer exists as shown in the lower right corner of FIG. 9. In each cycle among the cycles for determining the bits B[7:0], the bit b[ ] determination operation may comprise comparing the input signal Vin with the DAC output of the capacitive DAC 110 (labeled “IN>DAC” for brevity) to generate a comparison result indicating whether the input signal Vin is greater than the DAC output, for example, by utilizing the architecture shown in any figure among FIG. 1, FIG. 4A and FIG. 4B. According to the comparison result, the SARADC 100 can decide whether to add or subtract a reference level to the current DAC output voltage. It continues until the final decision is made. In addition, the reference level to be added to or subtracted from the current DAC output voltage in any cycle among the cycles for determining the bits B[7:0] may be determined in a similar manner as that described in the binary coding control scheme shown in FIG. 2, while the capacitance values {(4C*Y₁), (4C*Y₂), . . . , (4C*Y_{N-3+x}), 2C, 1C} of the series of capacitors are determined according to the hybrid coding control scheme. The associated determination operations regarding whether to add or subtract the reference level in the second cycle to the eighth cycle should be completed before the respective end of the previous cycles such as the first cycle to the seventh cycle (respectively labeled “+28 or −28”, . . . “+4 or −4”, “+2 or −2” and “+1 or −1” for brevity).

As shown in the lower left corner of FIG. 7, the encoder 140 which is embedded inside the main ADC architecture in the hybrid coding control scheme can be illustrated within the control sequence to indicate that the whole of the encoder cycles is embedded inside the ADC cycles. Right after the bit B[3] is resolved, the encoder 140 such as the 5b-to-4b encoder starts performing the 5b-to-4b conversion (or “the 5b-4b conversion) to convert the bits B[7:3] into the bits B′[6:3]. After the LSB B[0] is resolved, the output stage 150 such as the final D-FF (labeled “D-FF” for brevity) samples the bits {B′[6:3], B[2:0]}, the 7-bit data, as the 7 output bits ADC[6:0] for being output from the SARADC 100. Afterward, a new cycle of the control sequence of the hybrid coding control scheme begins from the bit B[7] immediately, faster than that of the control sequence of the non-binary coding control scheme. As the encoder 140 is coupled between the first signal path and the second signal path of the SAR logic circuit 130 to act as the embedded encoder such as the 5b-to-4b encoder for converting the bits B[7:3] into the bits B′[6:3], having no need to be implemented as the non-embedded encoder such as the 8b-to-7b encoder 60 outside the main ADC architecture, the SARADC 100 can complete the whole processing in time without any latency such as that of the architecture shown in FIG. 3, to achieve better overall performance. For brevity, similar descriptions for this embodiment are not repeated in detail here.

According to some embodiments, the output bit count N of the SARADC 100 (i.e., the number N of the N output bits ADC[N−1:0]), the bit count difference x between the input bit count (N+x−3) (i.e., the number (N−3+x) of the bits B[(N−1+x):3]) and the output bit count (N−3) (i.e., the number (N−3) of the bits B′[(N−1):3]) of the encoder 140 such as the (N+x−3) bit to (N−3) bit encoder, the predetermined unit capacitance value C, and/or the capacitor parameters {Yⱼ|j=1, 2, . . . , (N−3+x)} for arbitrarily configuring the capacitance values {(4C*Y₁), (4C*Y₂), . . . , (4C*Y_{N-3+x})} may vary as long as the implementation of the SARADC 100 will not be hindered. For example, when the output bit count N increases to be much greater than that of the above examples discussed in the embodiment shown in FIG. 9, that is, N>>7, the total latency (which may still be illustrated with “ . . . ” in the upper right corner of FIG. 9) in the control sequence of the non-binary coding control scheme will become much longer, and such total latency will never exist in the control sequence of the hybrid coding control scheme as shown in the lower right corner of FIG. 9. For brevity, similar descriptions for these embodiments are not repeated in detail here.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A successive approximation register (SAR) analog-to-digital converter (ADC), the SAR ADC (SARADC) comprising:
a capacitive digital-to-analog converter (DAC), arranged to generate at least one DAC output signal, the capacitive DAC comprising:
a capacitive DAC array, the capacitive DAC array being implemented with a combination of non-binary units and binary units, wherein the capacitive DAC array comprises a first sub-array and a second sub-array;
a comparator, coupled to the capacitive DAC, arranged to compare the at least one DAC output signal with a predetermined voltage level to generate at least one comparison result;
a SAR logic circuit, coupled to the capacitive DAC and the comparator, arranged to determine a plurality of bits according to the at least one comparison result, wherein the SAR logic circuit is arranged to control setting of the capacitive DAC in order to generate a set of first bits and a set of second bits among the plurality of bits with aid of the first sub-array and the second sub-array, respectively, for being output via a first signal path and a second signal path of the SAR logic circuit, respectively; and
an encoder, coupled between the first signal path and the second signal path of the SAR logic circuit, arranged to receive the set of first bits via the first signal path and encode the set of first bits into a set of third bits, allowing the SARADC to output the set of third bits and the set of second bits as output bits of the SARADC.

2. The SARADC of claim 1, wherein last two units among a series of units within the capacitive DAC array, the series of units comprising said combination of non-binary units and binary units, are fully binary, wherein the second sub-array comprises the last two units among the series of units.

3. The SARADC of claim 2, wherein the set of second bits are consecutive bits comprising a least significant bit (LSB) among the plurality of bits.

4. The SARADC of claim 2, wherein other units among the series of units are non-binary or partially binary, wherein the first sub-array comprises the other binary units among the series of units.

5. The SARADC of claim 4, wherein the set of first bits are consecutive bits comprising a most significant bit (MSB) among the plurality of bits.

6. The SARADC of claim 1, wherein any bit among the plurality of bits is arranged to control a corresponding capacitive unit in the capacitive DAC.

7. The SARADC of claim 1, wherein the SARADC is an N-bit SARADC whose output bits are N output bits, and the plurality of bits are (N+x) bits, wherein N is a positive integer at least greater than three, and x is a positive integer.

8. The SARADC of claim 7, wherein the (N+x) bits comprise bits B[(N−1+x):0], the set of first bits comprise bits B[(N−1+x):3] among the bits B[(N−1+x):0], and the set of second bits comprise bits B[2:0] among the bits B[(N−1+x):0]; and the set of third bits comprise bits B′[(N−1):3], and the N output bits comprise both of the bits B′[(N−1):3] and the bits B[2:0].

9. The SARADC of claim 8, wherein a series of first capacitors within the first sub-array, the series of first capacitors corresponding to the bits B[(N−1+x):3], have capacitance values of [(4C*Y₁):(4C*Y_{N-3+x})], respectively, wherein C is a predetermined unit capacitance value, and Y₁ to Y_{N-3+x} are positive integers.

10. The SARADC of claim 9, wherein a series of second capacitors within the second sub-array, the series of second capacitors corresponding to the bits B[2:1] among the bits B[2:0], have capacitance values of [2C:1C], respectively.

11. The SARADC of claim 10, wherein a summation of the capacitance values of the series of first capacitors and the capacitance values of the series of second capacitors is equal to ((2^{(N-1)}−1)*C).

12. The SARADC of claim 9, wherein the encoder is an (N+x−3) bit to (N−3) bit encoder for performing encoding processing on the bits B[(N−1+x):3] to generate the bits B′[(N−1):3] according to the following equation:
$$( B [ N - 1 + x ] * 4 {Y}_{1} ) + ( B [ N - 2 + x ] * 4 {Y}_{2} ) + … + ( B [ 3 ] * 4 {Y}_{N - 3 + x} ) = {B}^{′} [ ( N - 1 ) : 3 ] .$$

13. The SARADC of claim 7, wherein the encoder is an (N+x−3) bit to (N−3) bit encoder for performing encoding processing on the set of first bits to generate the set of third bits, wherein the encoding processing comprises receiving the set of first bits as non-binary input codes and summing up the non-binary input codes with scaling factors that are determined by corresponding unit cap sizes of a series of first capacitors within the first sub-array.

14. The SARADC of claim 1, wherein the set of first bits are consecutive bits comprising a most significant bit (MSB) among the plurality of bits, and the set of second bits are consecutive bits comprising a least significant bit (LSB) among the plurality of bits; and at end of a cycle in which the LSB is resolved among multiple cycles of the SARADC, the SARADC is arranged to start outputting the set of third bits and the set of second bits as the output bits of the SARADC.

15. The SARADC of claim 14, wherein the SARADC is arranged to complete determining the plurality of bits at the multiple cycles, respectively; and after the LSB is resolved, the SARADC is arranged to utilize an output stage of the SARADC to sample the set of third bits and the set of second bits as the output bits of the SARADC, for being output from the SARADC.

16. The SARADC of claim 14, wherein the SARADC is arranged to complete encoding the set of first bits into the set of third bits before the end of the cycle in which the LSB is resolved, for hiding encoding time, the encoding time of encoding the set of first bits into the set of third bits by the encoder, into a portion of cycles among the multiple cycles of the SARADC.

17. The SARADC of claim 1, wherein the capacitive DAC is a DAC equipped with a series of capacitors that are positioned on internal signal paths of the DAC, respectively.
